(19) United States
(12) Patent Application Publication
(10) Pub. No.: US 2001/0055727 A1
(43) Pub. Date: Dec. 27, 2001

(54) Resist material and method for pattern formation

(76) Inventors: Hiroshi Kubota, Niigata-ken (JP); Katsuya Takemura, Niigata-ken (JP); Takao Yoshihara, Niigata-ken (JP)

Correspondence Address: MYERS BIGEL SIBLEY & SAJOVEC, PO BOX 37428, RALEIGH, NC, 27627, US

(21) Appl. No.: 09/851,274

(22) Filed: May 8, 2001

(30) Foreign Application Priority Data
May 12, 2000 (JP) 2000-139537

(51) Int. Cl. G03F 7/004

(52) U.S. Cl. 430/270.1; 430/325; 430/326

(57) ABSTRACT

Provided are a resist material and a pattern formation method which have a good coating property, suppresses the occurrences of microbubbles in the solution and hardly generate a various kinds of defects causing a yield reduction in device step. Specifically, a resist material comprising a non-ionic surfactant containing neither a fluorine substituent nor a silicon-containing substituent in addition to a surfactant having a fluorine substituent and a pattern formation method therewith are provided.

### BACKGROUND OF THE INVENTION

1. Field of the Invention

The present invention relates to a novel resist material and a method for a pattern formation suitable for micro-lithography.

2. Description of the Related Art

Recently, accompanying with the trend of high integration and speed-up of LSIs, in a situation where the miniaturization of a pattern rule is required, far-ultraviolet radiation, X ray and electron beam lithography are considered to be promising as micro-lithography of the next generation.

At present, far-ultraviolet rays lithography employing a KrF excimer laser are commercialized, the processing of a pattern rule of 0.15 μm or less can be carried out with a chemically amplified resist material using acid as a catalyst. Moreover, as a light source of far-ultraviolet radiation of the next generation, a technology utilizing an ArF excimer laser of a high luminance becomes a focus of attention.

Since a diameter of a substrate becomes larger in progression, a resist material is desired to have a good coatability when it is coated on a substrate having a diameter of 8 inches. As a method for achieving this object, there may be some cases where a surfactant having a fluorine substituent is blended.

However, when a surfactant having a fluorine substituent is blended to a resist material, there may be some problems such as the occurrences of a variety of defects and microbubbles.

In a semiconductor device manufacturing step, the occurrences of a variety of defects such as a minute contaminant (defect) on a pattern surface and the like cause problems such as the yield reduction. Hence, a resist material in which the defects are not easily occurred is desired.

Moreover, the vibration during the transportation of a resist may cause microbubbles in the resist. Thus, a resist material in which these microbubbles hardly occur is desired.

### SUMMARY OF THE INVENTION

An object of the present invention is to provide a resist material and a pattern formation method in which the coating property is good, the occurrences of microbubbles in the solution is suppressed, and further occurrences of a variety of defects causing the yield reduction in the device manufacturing step is low.

As a result of a keen investigation by the present inventors for achieving the above-described object, it has been recognized that a resist material characterized by having a surfactant with a fluorine substituent as well as a non-ionic surfactant containing neither a fluorine substituent nor a silicon-containing substituent, can solve the problems such as the poor coating property of the resist material, the occurrence of a microbubble and the like, and reduce a variety of defects causing the yield reduction in the device manufacturing step. Then, the present invention has been accomplished.

A resist material of the present invention possesses a good coating property, does not generate microbubbles, and further suppresses the occurrences of a variety of defects, still further, is sensitive to high energy radiation or beam, and also excels in sensitivity, resolution and reproductivity. Moreover, a pattern of the present invention is not easily to become a form of overhang and is good at size control property. Therefore, a resist material of the present invention is preferably used particularly for a fine pattern formation material for manufacturing a super LSI at the exposure wavelength of a KrF, an ArF excimer laser owing to these properties.

### DETAILED DESCRIPTION OF THE PREFERRED EMBODIMENTS

Hereinafter, the present invention will be described in detail.

A resist material of the present invention may be either a positive type resist material or a negative type resist material.

A positive type resist material comprises a base resin being insoluble or sparingly soluble in alkali having an acidic functional group protected with an acid unstable group, and becoming soluble in alkali when the relevant acid-labile group is eliminated; an acid generator for generating acid by irradiation of far-ultraviolet radiation, X ray, electron beam or the like; commonly, an organic solvent for dissolving these components; and one or more surfactants containing a fluorine substituent and one or more non-ionic surfactants containing neither a fluorine substituent nor a silicon substituent. If necessary, it may comprise an additives such as a basic material or an acidic material or a dissolution inhibitor. The “insoluble or sparingly soluble in alkali” means that solubility in an aqueous solution of 2.38% by weight of TMAH (tetramethylammonium hydroxide) is 0 or less than 20 Å/sec, and “soluble in alkali” means that solubility in an aqueous solution of 2.38% by weight of TMAH is 20 to 300 Å/sec.

Although the present invention will be explained based on an example of positive type resist materials, the present invention may be also applicable to a negative resist material comprising a resin soluble in an alkaline solution, a crosslinker having a reactive group under an acidic condition such as a methylol group, an acid generator for generating an acid by irradiation of far-ultraviolet radiation, X ray, electron beam or the like, and further, commonly an organic solvent for dissolving these components.

The base resin used for the positive type resist, being insoluble or sparingly soluble in an alkaline solution and having an acidic functional group protected by an acid-labile group and becoming soluble in an alkaline solution when the relevant acid-labile group is eliminated, does not have a particular limitation so that a well-known resin can be used.

Specifically, a chemically amplified resist material having polyhydroxystyrene as a major component protected by two or more kinds of acid-labile groups in Japanese Patent Provisional Publication No. 9-211866/1997, a chemically amplified resist material having a polyhydroxy styrene as a major component protected by two or more kinds of acid-labile groups and acid-labile crosslinking groups in Japanese Patent Provisional Publication No. 11-190904/1999, and a chemically amplified resist material having a copolymer of polyacrylic resin and polyhydroxystyrene as a major component protected by an acid-labile group and a chemically amplified resist material for an ArF excimer laser having a polyacrylic resin or a polycycloolefinic resin protected by an acid-labile group in Japanese Patent Provisional Publication No. 6-266112/1994.

In the present invention, the acid generator used for a resist material of either a positive type or a negative type is one for generating an acid by irradiation of far-ultraviolet radiation, X ray, or electron beam, and does not have a particular limitation so that a well-known acid-generator can be used.

Specifically, for example, onium salts such as triphenylsulfonium trifluoromethanesulfonate, (p-tert-butoxyphenyl)diphenylsulfonium trifluoromethanesulfonate, tris(p-tert-butxyphenyl)sulfonium trifluoromethanesulfonate, triphenylsulfonium p-toluenesulfonate, (p-tert-butoxyphenyl)diphenylsulfonium p-toluenesulfonate, and tris(p-tert-butoxyphenyl)sulfonium p-toluenesulfonate, diazomethane derivatives such as bis(benzensulfonyl)diazomethane, bis(p-toluenesulfonyl)diazomethane, bis(cyclohexylsulfonyl)diazomethane, bis(n-butylsufonyl)diazomethane, bis(isobutylsulfonyl)diazomethane, bis(sec-butylsulfonyl)diazomethane, bis(n-propylsulfonyl)diazomethane, bis(isopropylsulfonyl)diazomethane, and bis(tert-butylsulfonyl)diazomethane, glyoxime derivatives such as bis-o-(p-toluenesulfonyl)-α-dimethylglyoxime, bis-o-(n-butanesulfonyl)-α-dimethylglyoxime are preferably employed. Moreover, β-ketosulfone derivatives such as 2-cyclohexylcarbonyl -2-(p-toluenesulfonyl)propane, disulfone derivatives such as diphenyldisulfone, nitrobenzyl sulfonate derivatives such as 2, 6-dinitrobenzyl p-toluenesulfonate, sulfonate derivatives such as 1, 2, 3-tris(methanesulfonyloxy)benzen, and imido-yl-sulfonate derivatives such as phthalimido-yl-triflate can be also used. It should be noted that the above-described acid generator may be employed singly or in combination of two or more kinds thereof.

The acid generator is preferably added in an amount of 0.2 to 15 parts by weight, more preferably 0.5 to 8 parts by weight based on 100 parts by weight of the base resin. When the amount is less than 0.2 parts by weight, an amount of acid generation upon exposure may be small so that sensitivity and resolution may be inferior. When the amount is more than 15 parts by weight, a transmittance of the resulting resist may be lowered so that the resolution may be inferior.

In the present invention, an organic solvent which may be usually used for a resist material of either a positive type or a negative type, does not have a particular limitation, and include ketones such as cyclohexanone and 2-n-amyl methyl ketone, alcohols such as 3-methoxybutanol, 3-methyl-3-methoxybutanol, 1-methoxy-2-propanol and 1-ethoxy-2-propanol, ethers such as propylene glycol monomethyl ether, ethylene glycol monomethyl ether, propylene glycol monoethyl ether, ethylene glycol monoethyl ether, propylene glycol dimethyl ether and diethylene glycol dimethyl ether, and esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate. One of these or a mixture of two or more thereof can be used.

The amount of the organic solvent used is preferably 100 to 5,000 parts by weight, more preferably 200 to 4,000 parts by weight, further preferably 300 to 3,000 parts by weight based on 100 parts by weight of the base resin.

A surfactant having a fluorine substituent employed in the present invention may include perfluoroalkylpolyoxyethylene ethanol, fluorinated alkyl ester, perfluoroalkylamine oxide, perfluoroalkylethylene oxide adduct, and fluorine containing organosiloxane compounds. Specific examples include Florad “FC-430” and “FC-431” (both by Sumitomo 3M Ltd.), Surflon “S-141”, “S-145”, “KH-20”, and “KH-40” (all by Asahi Glass, Co., Ltd.), Unidain “DS-401”, “DS-403” and “DS-451” (all by Daikin Industries, Ltd.), and Megafac “F-8151” (by Dainippon Ink & Chemicals, Inc.). Among them, “FC-430” and “KH-20” are more preferably used.

The amount of the surfactant having a fluorine substituent is preferably 10 to 2,000 ppm, more preferably 50 to 700 ppm based on the total amount of the resist material. When the amount is less than less than 10 ppm, the uniformity of film thickness may not be obtained and further, coating defects may be occurred. When the amount is more than 2,000 ppm, the resolution may be lowered.

A non-ionic surfactant containing neither a fluorine substituent nor a silicon containing substituent used in the present invention, does not have a particular limitation and preferably includes polyoxyethylene nonyl phenyl ether, polyoxyethylene alkyl ether, polyoxyethylene lauryl ether, polyoxyethylene higher alcohol ether wherein higher alcohol means acohol having six or more carbon atoms, polyoxyalkylene alkyl ether, polyoxyethylene derivative, and polyoxyethylene sorbitan monolaurylate are listed. The non-ionic surfactant having neither a fluorine substituent nor a silicon containing substituent may be used singly or in combination of two or more thereof.

The commercially available non-ionic surfactant includes Sunmorl “N-60 SM (polyoxyethylenen nonyl phenyl ether)”, “L-50 (polyoxyethylene alkyl ether)” and “SE-70 (polyoxyethylene alkyl ether)” (all by Nicca Chemical Co., Ltd.), Emulgen “108 (polyoxyethylene lauryl ether)”, “707 (polyoxyethylene higher alcohol ether)”, “709 (polyoxyethylene higher alcohol ether)”, “LS-106 (polyoxyalkylene alkyl ether)”, “LS-110 (polyoxyalkylene alkyl ether)”, “MS-110 (polyoxyalkylene alkyl ether)”, “A-60 (polyoxyethylene derivative)”, “B-66 (polyoxyethylene derivative)” and Rheodol “TW-L106 (polyoxethylene sorbitan monolaurylate)” (all by Kao Corporation). Among them, Emergen MS-110 and Reodor TW-L106 are preferably used.

The amount of the non-ionic surfactant containing neither a florine substituent nor a silicon containing substituent may be in the range of 10 to 2,000 ppm, particularly preferably 50 to 1,000 ppm based on the total amount of the resist material. When the amount is less than 10 ppm, the decrease of defects may not be obtained. When the amount is more than 2,000 ppm, a detriment such as lowered resolution or significant occurrence of scum may be caused.

A weight ratio of the non-ionic surfactant having neither a fluorine substituent nor a silicon containing substituent to the surfactant containing a fluorine substituent, that is, (non-ionic surfactant having neither a fluorine substituent nor a silicon containing substituent)/(surfactant containing a fluorine substituent) is preferably 0.1 or more, more preferably 0.1 to 100. When the weight ratio is less than 0.1, the various kinds of defects may not be reduced.

The resist material of the present invention may contain an additive such as a basic substance, an acidic substance, or a dissolution inhibitor, if necessity.

The basic substance include primary, secondary and tertiary aliphatic amines, mixed amines, aromatic amines, heterocyclic amines, nitrogen-containing compounds having a carboxyl group, nitrogen-containing compounds having a sulfonyl group, nitrogen-containing compounds having a hydroxy group, nitrogen-containing compounds having a hydroxyphenyl group, alcoholic nitrogen-containing compounds, amide derivatives, imide derivatives and the like. Particularly preferable basic substance may be tertiary amines, aniline derivatives, pyrolidine derivatives, pyridine derivatives, quinoline derivatives, amino acid derivatives, nitrogen-containing compounds having a hydroxy group, nitrogen-containing compounds having a hydroxyphenyl group, alcoholic nitrogen-containing compounds, amide derivatives, imide derivatives, tris{2-(methoxymethoxy)ethyl}amine, tris{2-(2-methoxyethoxy)ethyl}amine, tris[2-{(2-methoxyethoxy)methyl}ethyl]amine, 1-aza-15-crown-5 and the like.

It should be noted that the above-described basic substance can be used singly or in combination of two or more kinds thereof. The amount thereof is preferably 0.01 to 2 parts by weight, more preferably 0.01 to 1 parts by weight based on 100 parts by weight of the base resin. When the amount is less than 0.01 parts by weight, the effect by the addition thereof may not be obtained. When the amount is more than 2 parts by weight, the sensitivity may be excessively lowered.

The acidic substance does not have a particular limitation and specific examples thereof include phenol, cresol, catechol, resorcinol, pyrogallol, fluoroglycine, bis(4-hydroxyphenyl)methane, 2,2-bis(4′-hydroxyphenyl)propane, bis(4-hydroxyphenyl)sulfone, 1, 1, 1-tris(4′-hydroxyphenyl)ethane, 1, 1, 2-tris(4′-hydroxyphenyl)ethane, hydroxybenzophenon, 4-hydroxyphenylacetic acid, 3-hydroxyphenylacetic acid, 2-hydroxyphenylacetic acid, 3-(4- hydroxyphenyl)propionic acid, 3-(2-hydroxyphenyl)propionic acid, 2,5-dihydroxyphenylacetic acid, 3,4-dhydroxyphenylacetic acid, 1,2-phenylenediacetic acid, 1,3-phenylenediacetic acid, 1,4-phenylenediacetic acid, 1,2-phenylenedioxydiacetic acid, 1,4-phenylenedipropanic acid, benzoic acid, salicyclic acid, 4,4-bis(4′-hydroxyphenyl)valeric acid, 4-tert-butoxyphenylacetic acid, 4-(4-hydroxyphenyl)butyric acid, 3, 4-dihydroxymandelic acid, 4-hydroxymandelic acid and the like. Among them, salicyclic acid, 4,4-bis(4′-hydroxyphenyl)valeric acid are preferable. These can be used singly or in combination of two or more thereof.

The amount of an acidic substance is 5 parts by weight or less, preferably 1 part by weight or less based on 100 parts of the base resin. When the amount is more than 5 parts by weight, the resolution may be deteriorated.

The dissolution inhibitor include a compound having molecular weight 3,000 or less whose solubility in an alkaline developing solution changes by action of acid, more preferably, low molecular weight phenol having molecular weight of 2,500 or less and a compound having one portion or all of a carbonic acid derivative replaced by a acid-labile group.

Preferred examples of the dissolution inhibitor 3, 3′,5,5′-tetrafluoro[(1,1′-biphenyl)-4,4′-di-t-butoxycarbonyl], 4,4′-[2, 2,2-trifluoro-1-(trifluoromethyl)ethylidene]bisphenol-4,4′-di-t-butoxycarbonyl, bis(4-(2′-tetrahydropyranyloxy)phenyl)methane, bis(4-(2′-tetrahydrofuranyloxy)phenyl)methane, bis (4-tert-butoxyphenyl)methane, bis(4-tert-butoxycabonyloxyphenyl)methane, bis(4-tert-butoxycarbonylmethyloxyphenyl)methane, bis (4-(1′-ethoxyethoxy)phenyl)methane, bis(4-(1′-ethoxypropyloxy)phenyl)methane, 2,2-bis(4′-(2″-tetrahydropyranyloxy))propane, 2,2-bis(4-(2″-tetrahydrofuranyloxy)phenyl)propane, 2,2-bis(4′-tert-butoxyphenyl)propane, 2,2-bis(4′-tert-butoxycarbonyloxyphenyl)propane, 2,2-bis(4-tert-butoxycarbonylmethyloxyphenyl)propane, 2,2-bis(4′-(1″-ethoxyethoxy)phenyl)propane, 2,2-bis(4′-(1″-ethoxypropyloxy)phenyl)propane, tert-butyl 4,4-bis(4′-(2″-tetrahydropyranyloxy)phenyl)valerate, tert-butyl 4,4-bis(4′-(2″-tetrahydrofuranyloxy)phenyl)valerate, tert-butyl 4,4-bis(4′-tert-butoxyphenyl)valerate, tert-butyl 4,4-bis(4-tert-butoxycarbonyloxyphenyl)valerate, tert-butyl 4,4-bis(4′-tert-butoxycarbonylmethyloxyphenyl)valerate, tert-butyl 4,4-bis(4′-(1″-ethoxyethoxy)phenyl)valerate, tert-butyl 4,4-bis(4′-(1″-ethoxypropyloxy)phenyl)valerate, tris(4-(2′-tetrahydropyranyloxy)phenyl)methane, tris(4-(2′-tetrahydrofuranyloxy)phenyl)methane, tris(4-tert-butoxyphenyl)methane, tris (4-tert-butoxycarbonyloxyphenyl)methane, tris(4-tert-butoxycarbonyloxymethylphenyl)methane, tris (4 -(1′-ethoxyethoxy)phenyl)methane, tris(4-(1′-ethoxypropyloxy)phenyl)methane, 1,1,2-tris(4′-(2″-tetrahydropyranyloxy)phenyl)ethane, 1,1,2-tris(4′-(2″-tetrahydrofuranyloxy)phenyl)ethane, 1,1,2-tris(4′-tert-butoxyphenyl)ethane, 1,1,2-tris(4′-tert-butoxycarbonyloxyphenyl)ethane, 1,1,2-tris(4′-tert-butoxycarbonylmethyloxyphenyl)ethane, 1,1,2-tris(4′-(1′-ethoxyethoxy)phenyl)ethane, 1,1,2-tris(4′-(1′-ethoxypropyloxy)phenyl)ethane, t-butyl 2-trifluoromethylbenzenecarboxylate, t-butyl 2-trifluoromethylcyclohexanecarboxylate, t-butyl decahydronaphtalene-2,6-dicarboxylate, t-butyl cholate, t-butyl deoxycholate, t-butyl adamantanecarboxylate, t-butyl adamantyl acetate, tetra-t-butyl [1,1′-bicyclohexyl-3,3′,4, 4′-tetracarboxylate and the like.

The amount of the dissolution inhibitor in a resist material of the present invention may be 20 parts by weight or less, preferably 15 parts by weight or less based on 100 parts by weight of the solid portions of the resist material. When the amount is more than 20 parts by weight, heat resistance of the resist material may be lowered owing to the increased monomer content.

The present invention provides a chemically amplified resist material which contains one or more surfactants having a fluorine substituent, and one or more non-ionic surfactants having neither a fluorine substituent nor a silicon substituent, and which is preferably exposed by high energy radiation of a wavelength of 500 nm or less, X ray or electron beam.

Moreover, the present invention provides a pattern formation method comprising a step for coating the resist material of the present invention on a substrate, a step for subsequent heating, a sep for exposure to high energy radiation of a wavelength of 500 nm or less, X ray or electron beam via a photomask, then, a step for heating if necessary, and a step for developing the resist in a developing solution.

In order to form a pattern using a chemically amplified positive type resist material in accordance with the present invention, any well-known lithographic technique can be employed. For example, according to a spin coating technique or the like, the resist material is applied onto a silicon wafer to a thickness of 0.5 to 2.0 μm , and prebaked on a hot plate at 60 to 150° C. for 1 to 10 minutes, preferably 80 120(C for 1 to 5 minutes. Then, a mask for the targeted patten formation is placed above the obtained film of the resist mateial, which is irradiated in an approximate amount of 1 to 200 mJ/cm², preferably 10 to 100 mJ/cm², to high-energy radiation having wavelength of 500 nm or less such as far ultraviolet radiation, excimer laser and X-ray. Then, it is subjected to a post-exposure bake (PEB) on a hot plate at 60 to 150° C. for 1 to 5 minutes, preferably 80 to 120° C. for 1 to 3 minutes. Furthermore, it is developed for 0.1 to 3 minutes, preferably 0.5 to 2 minutes in a developing solution of aqueous alkaline such as 0.1 to 5% by weight, preferably 2 to 3% by weight tetramethylammonium hydroxide (TMAH), using an ordinary method such as dip, puddle, spray or the like. As a result, the targeted pattern on the substrate is formed. It should be noted that the material of the present invention is particularly suitable for a fine patterning using far-ultraviolet radiation of 254 to 193 nm or excimer laser, X ray or electron beams, among various types of high energy radiation. Moreover, in the case where it is excluded from the upper limit and the lower limit of the above-described range, the targeted pattern may not be obtained.

Hereinafter, the present invention will be specifically described using examples and comparative examples. However, these examples are not to be construed to limit the scope of the invention.

1. The used resist composition

The resists A to E having the following compositions were used as positive type of chemically amplified resist.

(Composition of the resist A)

| | | |
|---|---|---|
| Polyhydroxystyrene having weight average | 80 | parts by weight |
| molecular weight of 11,000 wherein 14 mole % | | |
| of the total hydroxyl groups are protected by | | |
| 1-ethoxyethyl group and 13 mole % of the total | | |
| hydroxyl groups are protected by tert- | | |
| butoxycarbonyl group | | |
| Bis(cyclohexylsulfonyl)diazomethane | 5 | parts by weight |
| Tributylamine | 0.125 | parts by weight |
| Propyleneglycol monomethylether acetate | 450 | parts by weight |

(Composition of the resist B)

| | | |
|---|---|---|
| Polyhydroxystyrene having weight average | 80 | parts by weight |
| molecular weight of 25,000 wherein 20 mole % | | |
| of the total hydroxyl groups are crosslinked by | | |
| 1-ethoxyethyl group and 5 mole % of the total | | |
| hydroxyl groups are crosslinked by tert- | | |
| butoxycarbonyl group, and further 4 mole % of | | |
| the total hydroxyl groups are crosslinked by 1,2- | | |
| propanedioldivinylether | | |
| Triphenylsulfonium tosylate | 2 | parts by weight |
| Salicyclic acid | 1 | part by weight |
| Tributylamine | 0.125 | parts by weight |
| Propyleneglycol monomethylether acetate | 450 | parts by weight |

(Composition of the resist C)

| | | |
|---|---|---|
| Poly[(tert-butyl acrylate)-(hydroxystyrene)] | 80 | parts by weight |
| (copolymer having weight average molecular | | |
| weight of 10,000 and molar ratio of 30:70) | | |
| Bis(cyclohexylsulfonyl)diazomethane | 5 | parts by weight |
| Salicyclic acid | 1 | part by weight |
| Tributylamine | 0.125 | parts by weight |
| Propyleneglycol monomethylether acetate | 450 | parts by weight |

(composition of the resist D)

| | | |
|---|---|---|
| Poly[(tert-butyl methacrylate)-(methyl | 80 | parts by weight |
| methacrylate)-(methacrylic acid)](copolymer | | |
| having weight average molecular weight of | | |
| 12,000 and molar ratio 40:40:20) | | |
| Triphenylsulfonium perfluorobutylsulfonate | 2 | parts by weight |
| Tributylamine | 0.125 | parts by weight |
| Mixed solvent of propyleneglycol | 450 | parts by weight |
| monomethylether acetate and lactic acid (weight | | |
| ratio of 7:3) | | |

(Composition of the resist E)

| | | |
|---|---|---|
| Poly[(t-butyl 5-norbornene-2-carboxylate)-(maleic | 80 | parts by weight |
| anhydride)-(5-norbornene-2,3-dicarboxylic acid)] | | |
| (copolymer having weight average molecular | | |
| weight of 9,000 and molar ratio 30:50:20) | | |
| Triphenylsulfonium perfluorobutylsulfonate | 2 | parts by weight |
| Tributylamine | 0.125 | parts by weight |
| cyclohexanone | 450 | parts by weight |

2. The used surfactant

As an working example of the present invention, the following combinations of surfactants (solely referred to as “surfactant”) 1 and 2 were used. The amount used thereof are also shown below.

(Surfactant 1: combination of a surfactant containing a fluorine substituent and a surfactant containing neither a fluorine substituent nor a silicon-containing substituent)

| | |
|---|---|
| Fluorosurfactant: KH-20 (by Asahi Glass, Co., Ltd.) | 300 ppm |
| Emergen MS-110 (by Kao Corporation) | 300 ppm |

(Surfactant 2: combination of a surfactant containing a fluorine substituent and a non-ionic surfactant containing neither a fluorine substituent nor a silicon-containing substituent)

| | |
|---|---|
| Fluorosurfactant: KH-20 (by Asahi Glass, Co., Ltd.) | 300 ppm |
| Reodor TW-L106 (by Kao Corporation) | 300 ppm |

As comparative examples, the following surfactants 3 and 4 were used.

(Surfactant 3: only a surfactant containing a fluorine substituent)

| | |
|---|---|
| Fluorosurfactant: KH-20 (by Asahi Glass, Co., Ltd.) | 300 ppm |
| (Surfactant 4: only a surfactant containing a fluorine | |
| substituent) | |
| Fluorosurfactant: FC-430 (by Sumitomo 3M Co., Ltd.) | 300 ppm |

3. Method for evaluating contaminants (defects) on the pattern surface

The resist composition shown in Table 1 was filtered using a 0.05 82 m Teflon filter in several times. The resist liquid obtained was spin-coated on a silicon wafer and baked at 100° C. for 90 seconds using a hot plate so as to obtain the resist film with the thickness of 0.55 82 m. This was exposed at 1:1 of a line and space pattern of 0.25 82 m using KrF excimer laser scanner (NSR-S 202A by Nikon Corporation). After the exposure, it was baked at 110° C. for 90 seconds. Then, a patterned wafer for evaluation was prepared by performing development for 60 seconds in an aqueous solution of 2.38 wt % tetramethylammonium hydroxide. As the evaluation on the obtained patterned wafer, the number of contaminants (defects) generated on the surface of the pattern was counted based on SEM observation.

4. Method for evaluating microbubbles

The resist composition shown in Table 1 was filtered using a 0.05 μm Teflon filter in several times, filled in a gallon bottle and shaken. In the liquid particle counter (KL-20 by Lion, Co., Ltd.), number shift for particles of 0.22 82 m or more in a 1 ml was evaluated after the shake.

5. Method for evaluating coating property

The resist composition shown in Table 1 was filtered using a 0.05 82 m Teflon filter in several times. The resist liquid obtained was spin-coated on a 8 inches silicon wafer and baked at 100° C. for 90 seconds using a hot plate so as to obtain the resist film with the thickness of 0.55 82 m. Twenty sheets were coated and evaluated based on frequency of occurring coating dots as an index of coating property. When the frequency of coating dots is lower, the coating property is considered to be better. Furthermore, the thickness was measured at 35 points at the 5 mm pitches in the horizontal direction of an orientation flat from the center of a wafer. The range of variation of thickness is also made as an index of the coating property. When the range is smaller, the coating property is considered to be better.

6. Method for evaluating exposure

The resist composition shown in Table 1 was filtered using a 0.05 82 m Teflon filter in several times. The resist liquid obtained was spin-coated on a 8 inches silicon wafer and baked at 100° C. for 90 seconds using a hot plate so as to obtain the resist film with the thickness of 0.55 82 m. This was exposed while changing the amount of exposure and focus positions using the KrF excimer laser stepper (NSR202A NA=0.6 by Nikon Corporation). After the exposure, it was baked at 100° C. for 90 seconds, a positive type pattern was obtained by performing development for 60 seconds in an aqueous solution of 2.38 wt % tetramethylammonium hydroxide. Although the resists D and E are resists for ArF excimer laser, these were evaluated by the KrF excimer laser stepper. A focus margin of the resist pattern having the line and space of 0.18 82 m was measured. When the focus margin is larger, the resolution is considered to be better.

7. Results

The results are shown in Table 1.

TABLE 1

| | | | num. of contaminants | num. of liquid particles | | frequency of | range of variation of | |
|---|---|---|---|---|---|---|---|---|
| | | | on the pattern surface | right after | 24 hrs later | coating dots | coated film thickness | forcus margin |
| | surfactant | resist | (number) | (number/ml) | (number/ml) | (%) | (Å) | (μm) |
| Example 1 | 1 | A | 2 | 1.7 | 1.3 | 0 | 12 | 1.3 |
| Example 2 | 1 | B | 3 | 2.4 | 1.3 | 0 | 10 | 1.2 |
| Example 3 | 1 | C | 1 | 2.5 | 1.2 | 0 | 13 | 1.4 |
| Example 4 | 1 | D | 2 | 2.2 | 1.0 | 0 | 12 | 1.3 |
| Example 5 | 1 | E | 3 | 1.9 | 1.3 | 0 | 14 | 1.3 |
| Example 6 | 2 | B | 2 | 2.3 | 1.4 | 0 | 11 | 1.4 |
| Comp. Ex. 1 | 3 | A | 41 | 11 | 8 | 0 | 12 | 1.3 |
| Comp. Ex. 2 | 3 | B | 52 | 10 | 9 | 0 | 10 | 1.2 |
| Comp. Ex. 3 | 3 | C | 66 | 13 | 7 | 0 | 13 | 1.4 |
| Comp. Ex. 4 | 3 | D | 58 | 12 | 10 | 0 | 12 | 1.3 |
| Comp. Ex. 5 | 3 | E | 44 | 12 | 8 | 0 | 14 | 1.3 |
| Comp. Ex. 6 | 4 | B | 48 | 123 | 115 | 0 | 1 | 1.2 |

1. A resist material comprising one or more surfactants having a fluorine substituent and one or more non-ionic surfactants having neither a fluorine substituent nor a silicon-containing substituent.

2. A resist material according to claim 1 wherein said non-ionic surfactant is one or more compounds selected from the group consisting of polyoxyalkylene alkyl ether esters, polyoxyalkylene alkyl ether, polyoxyalkylene dialkyl ether, polyoxyalkylene aralkyl alkyl ether, polyoxyalkylene aralkyl ether, polyoxyalkylene diaralkyl ether, polyoxyalkylene laurylates.

3. A resist material according to claim 1 being a chemically amplified resist material and subject to exposure to high energy radiation of 500 nm or less, X ray or electron beam.

4. A resist material according to claim 2 being a chemically amplified resist material and subject to exposure to high energy radiation of 500nm or less, X ray or electron beam.

5. A pattern formation method comprising a step for coating of a resist material according to claim 1 on a substrate, a step for a subsequent heat treatment, a step for exposure through a photomask to a high energy radiation having wavelength of 500 mm or less, an X ray or an electron beam, a step for an optional heat treatment, and a step for development in a developing solution.

6. A pattern formation method comprising a step for coating of a resist material according to claim 2 on a substrate, a step for a subsequent heat treatment, a step for exposure through a photomask to a high energy radiation having wavelength of 500 mm or less, an X ray or an electron beam, a step for an optional heat treatment, and a step for development in a developing solution.

7. A pattern formation method comprising a step for coating of a resist material according to claim 3 on a substrate, a step for a subsequent heat treatment, a step for exposure through a photomask to a high energy radiation having wavelength of 500 mm or less, an X ray or an electron beam, a step for an optional heat treatment, and a step for development in a developing solution.

8. A pattern formation method comprising a step for coating of a resist material according to claim 4 on a substrate, a step for a subsequent heat treatment, a step for exposure through a photomask to a high energy radiation having wavelength of 500 mm or less, an X ray or an electron beam, a step for an optional heat treatment, and a step for development in a developing solution.
